(19) United States
(12) Patent Application Publication
(10) Pub. No.: US 2010/0295037 A1
(43) Pub. Date: Nov. 25, 2010

(54) Thin film transistor, display, and electronic apparatus

(75) Inventor: Katsuyuki Hironaka, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/662,033

(22) Filed: Mar. 29, 2010

(30) Foreign Application Priority Data
May 21, 2009 (JP) 2009-122756

(51) Int. Cl. H01L 29/786; H01L 29/04; H01L 33/16; H01L 33/26

(52) U.S. Cl. 257/43; 257/57; 257/59; 257/E29.296; 257/E29.003; 257/E33.004; 257/E33.037

(57) ABSTRACT

Disclosed herein is a thin film transistor including: a semiconductor layer including an amorphous oxide, and a source electrode and a drain electrode which are provided in contact with the semiconductor layer. The source electrode and the drain electrode are formed by use of iridium or iridium oxide.

### BACKGROUND OF THE INVENTION

1. Field of the Invention

The present invention relates to a thin film transistor using a semiconductor layer having an amorphous oxide, and to a display and an electronic apparatus which include the thin film transistor.

2. Description of the Related Art

Application of a semiconductor layer having an amorphous oxide (hereinafter referred to as oxide semiconductor layer) formed by using In, Zn, Ga and O as an active layer in thin film transistors for driving flat panel displays such as liquid crystal displays and organic EL (electroluminescence) displays, has been investigated. Since the oxide semiconductor layer is formed at room temperature by vapor deposition or sputtering, it can be formed on a plastic substrate. Besides, it is said that in this type of thin film transistor, Au/Ti, Pt/Ti, or zinc gallium oxide is used for forming source/drain electrodes provided in contact with the oxide semiconductor layer, and, therefore, good transistor characteristics can be obtained (see, for example, Japanese Patent Laid-open No. 2006-173580 referred to as Patent Document 1 hereinafter and K. Nomura, H. Ohta, A. Takagi, T. Kamiya, M. Hirano, and H. Hosono, Nature (London), Vol. 432, pp. 488 to 492, 2004, referred to as Non-patent Documents 1 hereinafter).

### SUMMARY OF THE INVENTION

However, the amorphous oxide constituting the oxide semiconductor layer is susceptible to reduction by hydrogen, nitrogen or the like. Such reduction of the amorphous oxide would cause deterioration of the oxide semiconductor layer, which, in turn, leads to deterioration of transistor characteristics, such as scattering of threshold voltage of the thin film transistor or variations in current (Ids)-voltage (Vds) characteristic of the thin film transistor.

Thus, there is a desire for a thin film transistor in which reduction-induced deterioration of an oxide semiconductor layer can be prevented and which can thereby maintain stable characteristics for a long time. There is also a desire for a display and an electronic apparatus in which the thin film transistors are used and which are excellent in long-term reliability accordingly.

In order to meet the above-mentioned desires, according to an embodiment of the present invention, there is provided a thin film transistor including a semiconductor layer having an amorphous oxide, and a source electrode and a drain electrode which are provided in contact with the semiconductor layer. Particularly, the source electrode and the drain electrode are formed by use of iridium or iridium oxide.

In accordance with another embodiment of the invention, there is provided a display which has pixel electrodes connected to the thin film transistors configured as above-mentioned. According to a further embodiment of the invention, there is provided an electronic apparatus which includes the thin film transistors.

In the thin film transistor according to the embodiment of the present invention as above-mentioned, iridium or iridium oxide constituting the source electrode and the drain electrode has a preventive effect on diffusion of reducing atoms or molecules, such as those of hydrogen and nitrogen, and on diffusion of oxygen. Therefore, reducing atoms or molecules such as those of hydrogen and nitrogen are prevented from being supplied through diffusion into the semiconductor layer having the amorphous oxide, and, simultaneously, oxygen is prevented from being lost through diffusion from the semiconductor layer having the amorphous oxide. As a result, the semiconductor layer having the amorphous oxide can be restrained from deterioration due to reduction and from deterioration due to oxygen defects.

Thus, according to embodiments of the present invention, the semiconductor layer having the amorphous oxide can be restrained from deterioration due to reduction and from deterioration due to oxygen defects, and, therefore, stability of thin film transistor characteristics can be maintained for a long period of time. In addition, it is made possible to maintain long-term reliability of the display and the electronic apparatus which are configured by use of the thin film transistor.

### BRIEF DESCRIPTION OF THE DRAWINGS

FIG. 1 is a sectional view of a thin film transistor of the bottom gate type according to a first embodiment of the present invention;

FIGS. 2A to 2D show manufacturing steps of the thin film transistor according to the first embodiment;

FIG. 3 is a sectional view of a thin film transistor according to a modification of the first embodiment;

FIG. 4 is a sectional view of a thin film transistor of the top gate type according to a second embodiment of the invention;

FIGS. 5A to 5D show manufacturing steps of the thin film transistor according to the second embodiment;

FIG. 6 is a sectional view of a liquid crystal display according to a third embodiment of the invention;

FIG. 7 shows an example of a circuit configuration of the liquid crystal display;

FIG. 8 is a sectional view of a liquid crystal display according to a fourth embodiment of the invention;

FIG. 9 is a sectional view of an organic EL display according to a fifth embodiment of the invention;

FIG. 10 shows an example of a circuit configuration of the organic EL display;

FIG. 11 is a sectional view of an organic EL display according to a sixth embodiment of the invention;

FIG. 12 is a perspective view of a television using a display according to an embodiment of the invention;

FIGS. 13A and 13B are perspective views of a digital camera using a display according to an embodiment of the invention, wherein FIG. 13A is a perspective view from the front side, and FIG. 13B is a perspective view from the rear side;

FIG. 14 is a perspective view of a notebook sized personal computer using a display according to an embodiment of the invention;

FIG. 15 is a perspective view of a video camera using a display according to an embodiment of the invention; and

FIGS. 16A to 16G are perspective views of a portable terminal device, for example, a cellular phone, using a display according to an embodiment of the invention, wherein FIG. 16A is a front view of the device in an opened state, FIG. 16B is a side view of the device, FIG. 16C is a front view of the device in a closed state, FIG. 16D is a left side view of the device, FIG. 16E is a right side view of the device, FIG. 16F is a top view, and FIG. 16G is a bottom view.

### DETAILED DESCRIPTION OF THE PREFERRED EMBODIMENTS

Now, embodiments of the present invention will be described below referring to the drawings, in the following order.
1. First Embodiment (bottom-gate thin film transistor)
2. Second Embodiment (top-gate thin film transistor)
3. Third Embodiment (an example of liquid crystal display configured by use of the bottom-gate thin film transistor)
4. Fourth Embodiment (an example of liquid crystal display configured by use of the top-gate thin film transistor)
5. Fifth Embodiment (an example of organic EL display configured by use of the bottom-gate thin film transistor)
6. Sixth Embodiment (an example of organic EL display configured by use of the top-gate thin film transistor)
7. Seventh Embodiment (an example of electronic apparatus)

### 1. First Embodiment

### <Configuration of Thin Film Transistor>

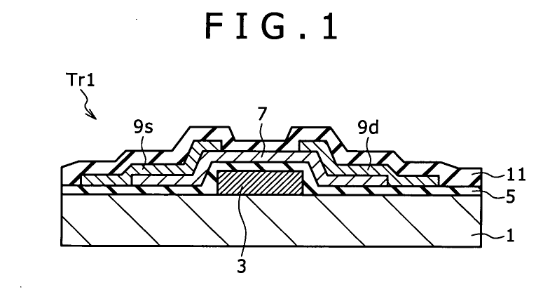

FIG. 1 shows a sectional view of a thin film transistor Tr1 according to a first embodiment of the present invention. The thin film transistor Tr1 shown in the figure is a bottom-gate thin film transistor in which a semiconductor layer (oxide semiconductor layer) having an amorphous oxide is used as an active layer. The thin film transistor Tr1 is configured as follows.

A gate electrode 3 is formed in a pattern over a substrate 1, and a gate insulating film 5 is provided in the state of covering the gate electrode 3 by use of an oxide material. A semiconductor layer 7 having an amorphous oxide (the semiconductor layer will hereinafter be referred to as oxide semiconductor layer) is provided on the gate insulating film 5 at a position on the upper side of the gate electrode 3. A source electrode 9s and a drain electrode 9d formed by use of iridium (Ir) or iridium oxide (IrO₂) are provided over the gate insulating film 5 (accompanied by the oxide semiconductor layer 7 provided thereon) at positions on opposite sides of the gate electrode 3. Further, the upper side of the gate insulating film 5 accompanied by the oxide semiconductor layer 7, the source electrode 9s and the drain electrode 9d provided thereover is covered by an insulating film 11 formed by use of an oxide material.

Consequently, the oxide semiconductor layer 7 is covered with the source electrode 9s and the drain electrode 9d which are formed by use of iridium or iridium oxide, and with the gate insulating film 5 and the insulating film 11 which are each formed by use of an oxide material. Now, details of the components of the thin film transistor Tr1 will be described below, in the order from the side of the substrate 1.

It suffices for the substrate 1 to be so configured that insulation is maintained on the face side thereof. Thus, a glass substrate, a plastic substrate, a substrate prepared by covering a metallic foil substrate with an insulating film, or the like may be used as the substrate 1. The substrate 1 is preferably covered on the face side thereof with a silicon oxynitride film for preventing diffusion of hydrogen. Particularly, the plastic substrate and the substrate obtained by covering a metallic foil substrate with an insulating film yield substrates which can be bent in a flexible manner.

As the glass substrate, an alkali-free glass substrate may be used. Besides, examples of the material which can be used to form the plastic substrate include polyether sulfone (PES), polyethylene terephthalate (PET), polyethylene naphthalate (PEN), polyolefins (PO), polypyromellitimide (PPI), and poly-p-phenylene terephthalamide (Kevlar). Of these materials, preferred from the viewpoint of heat resistance are polyether sulfone (PES), polyolefins (PO), polypyromellitimide (PPI), and poly-p-phenylene terephthalamie (Kevlar). Further, as the metallic foil substrate, a stainless steel substrate may be used, for example.

The material of the gate electrode 3 is not particularly limited, and a material having process compatibility and good conductivity may be used. Examples of the material include a laminate structure Cu (100 nm)/Ti (10 nm), a laminate structure of Mo (100 nm)/Ti (10 nm), and, further, a laminate structure of Al (100 nm)/Ti (nm).

The gate insulating film 5 is formed by use of an oxide material. Particularly preferable oxide materials are those having an ability to supply oxygen. Examples of such oxide material include Y₂O₃, Al₂O₃, Ta₂O₅, HfO₂, MgO, ZrO₂, Nb₂O₅, Sm₂O₃, Eu₂O₃, Ga₂O₃, Dy₂O₃, Ho₂O₃, Er₂O₃, Tm₂O₃, and SiO₂. Besides, the gate insulating film 5 may have a laminate structure of a film of such an oxide material with a film of other insulating material than oxide material (for example, a nitride film). Where the gate insulating film 5 has a laminate structure, the interface layer on the side of contact with the oxide semiconductor layer 7 is formed by use of the oxide material.

The oxide semiconductor layer 7 has an amorphous oxide; typically, a layer having an amorphous oxide including In, Zn, Ga, and O is used as the oxide semiconductor layer 7. Other than this typical example, the oxide semiconductor layer 7 may have an amorphous oxide containing at least one element selected from among Al, Ga, In, Zn, Mg, Ca, Sn, and Sb. Furthermore, for the purpose of stabilizing the oxygen in the amorphous oxide, the amorphous oxide may contain at least one element selected from among Mg, Y, Hf, Zr, Ta, Nb, and Ir in an amount of 5 to 10 at. %.

In the thin film transistor Tr1 using the oxide semiconductor layer 7 as above, it is possible by controlling the compositional ratio of the other materials than oxygen to control the threshold voltage with good reproducibility. For example, in the case of an oxide semiconductor layer 7 having a thin film of amorphous InZnO, it is possible, by controlling the atomic ratio of In/Zn to within the range of from 1.0 to 3.0, to control the threshold voltage to within the range of 2 to 10 V with good reproducibility. In the case of an oxide semiconductor layer 7 having an amorphous InGaZnO thin film, it is possible to control the threshold voltage to within the range of 2 to 10 V by controlling the atomic ratios so that In/Ga is from 0.5 to 1.5, In/Zn is from 0.5 to 2.5, and Ga/Zn is from 1.0 to 2.0. Besides, the source-drain current (Ids) has a value of from 1.0×10⁻⁴ to 2.0×10⁻³ A.

The source electrode 9s and the drain electrode 9d are formed by use of iridium (In) or iridium oxide (IrO₂). The source electrode 9s and the drain electrode 9d may each have a laminate structure. Particularly, it is important that the portion, in contact with the oxide semiconductor layer 7, of each of the electrodes 9s and 9d has a layer including at least one of iridium (Ir) and iridium oxide (IrO₂). In this case, it is preferable that a layer having a highly conductive material is provided on the layer having at least one of iridium (Ir) and iridium oxide (IrO₂).

An examples of the laminate structure of each of the source electrode 9s and the drain electrode 9d is Cu (100 nm)/Ti (10 nm)/Ir (50 nm)/IrO₂ (30 nm) in this order from the upper side. Another example is Cu (100 nm)/Ti (10 nm)/Ir (50 nm). In these laminate structures, for preventing diffusion of oxygen, the thickness of the Ir layer is desirably not less than 5 nm.

The insulating film 11 is formed by use of an oxide material similar to that used for the gate insulating film 5. Particularly preferably, an oxide material having an ability to supply oxygen is used to form the insulating film 11, like the oxide material used to form the gate insulating film 5. Preferable examples of such an oxide material include Y₂O₃, Al₂O₃, Ta₂O₅, HfO₂, MgO, ZrO₂, Nb₂O₅, Sm₂O₃, Eu₂O₃, Ga₂O₃, Dy₂O₃, Ho₂O₃, Er₂O₃, Tm₂O₃, and SiO₂. Besides, the insulating film 11 may have a laminate structure of a film of the oxide material with a film of other insulating material than oxide material (for example, a nitride film). Where the insulating film 11 has such a laminate structure, the interface layer on the side of contact with the oxide semiconductor layer 7 is formed by use of the oxide material.

In the thin film transistor Tr1 configured as above, iridium (Ir) or iridium oxide (IrO₂) used to form the source electrode 9s and the drain electrode 9d has a preventive effect on diffusion of reducing atoms or molecules such as those of hydrogen and nitrogen and, further, on diffusion of oxygen. As a result, reducing atoms or molecules such as those of hydrogen and nitrogen are prevented from being supplied through diffusion to the oxide semiconductor layer 7, and, simultaneously, oxygen is prevented from being lost through diffusion from the oxide semiconductor layer 7 with an intermediary of the source electrode 9s and the drain electrode 9d. Besides, of the oxide semiconductor layer 7, other portions than the portions in contact with the source electrode 9s or the drain electrode 9d are covered with either of the gate insulating film 5 and the insulating film 11 each of which has the oxide material. Therefore, oxygen is also prevented from being lost from these insulating films 5 and 11 by diffusion. Then, it is possible to prevent diffusion of atoms or molecules such as those of hydrogen and nitrogen and losing of oxygen by diffusion, which might otherwise occur during the subsequent processes.

As a result, deterioration of the oxide semiconductor layer 7 due to reduction and deterioration of the oxide semiconductor layer 7 due to oxygen defects can be restrained, and the characteristics of the thin film transistor Tr1 can be stabilized for a long period of time.

Furthermore, iridium (Ir) and iridium oxide (IrO₂) which can be used to form the source electrode 9s and the drain electrode 9d are better in adhesion to the amorphous oxide used to form the oxide semiconductor layer 7, as compared with Au and Pt. Accordingly, it is possible to prevent exfoliation at the interfaces between the electrodes 9s, 9d and the oxide semiconductor layer 7 from occurring due to internal stress. In this point, also, enhanced reliability can be attained.

In addition, in the thin film transistor Tr1, by controlling the compositional ratio of the amorphous oxide material used to form the oxide semiconductor layer 7, as above-mentioned, the threshold voltage is controlled to within the range of from 2 to 10 V with good reproducibility, and the source-drain current (Ids) is made to have a value of 1.0×10⁻⁴ to 2.0×10⁻³ A. Therefore, as will be shown in third and latter embodiments of the present invention, the thin film transistor Tr1 is optimum for use as a driving transistor in liquid crystal displays and organic EL displays, and can precisely drive the displays with good stability for a long time.

### <Manufacturing Method for Thin Film Transistor>

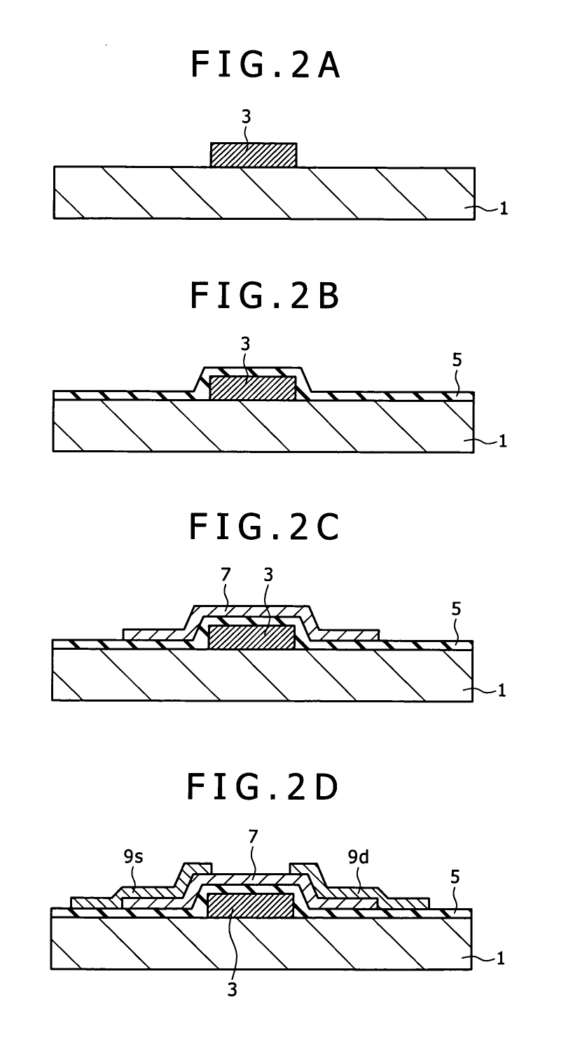

A method of manufacturing the thin film transistor Tr1 according to the first embodiment will be described in detail below, referring to sectional manufacturing-step views shown in FIG. 2.

First, as shown in FIG. 2A, a substrate 1 which is insulating on the face side is prepared. The substrate 1, for example, has a silicon oxynitride film which is formed for preventing diffusion of hydrogen in a thickness of 300 nm over a 1 mm-thick alkali-free glass substrate, plastic substrate or stainless steel substrate. The method of forming the silicon oxynitride film is not particularly limited; for example, plasma enhanced CVD, sputtering or the like may be used.

Next, a gate electrode 3 is formed in a pattern over the substrate 1. In this case, component layers of a stacked film of Cu (100 nm)/Ti (10 nm) or Mo (100 nm)/Ti (10 nm) are formed by sputtering, sequentially from the Ti layer. Thereafter, a resist pattern is formed on the stacked film by photolithography, and, by using the resist pattern as a mask, the stacked film is etched in a pattern, to obtain the gate electrode 3. The pattern etching of the stacked film may be dry etching such as RIE (reactive ion etching) or may be wet etching.

Subsequently, as shown in FIG. 2B, a gate insulating film 5 having the above-mentioned oxide material is formed over the substrate 1 provided thereon with the gate electrode 3. The method of forming the gate insulating film 5 is not particularly limited; for example, plasma enhanced CVD, sputtering, atomic layer deposition (ALD) or the like may be used.

For instance, where the gate insulating film 5 is formed using aluminum oxide as the oxide material, the film is formed in a thickness of 100 nm by plasma enhanced CVD, sputtering or the like, and in a thickness of 30 nm by ALD.

In the case of forming the gate insulating film 5 by ALD, when a substrate of a highly heat-resistant material such as a glass substrate, a metallic foil substrate, etc. is used as the substrate 1, the gate insulating film 5 having the oxide material may be formed by alternately supplying source gases respectively containing the atoms to the substrate 1 being held at a temperature of 150 to 350° C. The source gases to be used in this instance, on the basis of each oxide material, are as follows.
Al₂O₃: Al(CH₃)₃, H₂O
HfO₂: Hf[N(CH₃)₂]₄, H₂O
Y₂O₃: Y(Cp(CH₃)₃, H₂O (Cp stands for cyclophentadienyl)
Ta₂O₅: Ta(OC₂H₅)₅, H₂O
MgO: Mg(thd)₂, O₃ (thd stands for 2,2,6,6-tetramethyl-3,5-heptanedionate)
ZrO₂: ZrCp₂Cl₂, O₃
Nb₂O₃: Nb(OEt)₅, H₂O
CeO₂: Ce(thd)₄, O₃
Nd₂O₅: Nd(thd)₃, O₃
Sm₂O₃: Sm(thd)₃, O₃
Eu₂O₃: Eu(thd)₃, O₃
Ga₂O₃: Ga(acac)₃, O₃ (acac stands for acetylacetonate)
Dy₂O₃: Dy(thd)₃, O₃
Ho₂O₃: Ho(thd)₃, O₃
Er₂O₃: Er(thd)₃, O₃
Tm₂O₃: Tm(thd)₃, O₃
SiO₂: SiCl₂H₂, H₂O

In the case where the gate insulating film 5 is formed by ALD, when a substrate of a material comparatively low in heat resistance such as a plastic substrate is used as the substrate 1, the gate insulating film 5 having the oxide material may be formed by alternately supplying source gases respectively containing the atoms to the substrate 1 while the substrate 1 is not heated or is heated at a low temperature. In this instance, the source gases to be supplied, on the basis of each oxide material, are as follows.
Al₂O₃: Al(CH₃)₃, oxygen gas containing at least 10 wt. % of O₃
HfO₂: Hf[N(CH₃)₂]₄, oxygen gas containing at least 10 wt. % of O₃
Y₂O₃: Y(CpCH₃)₃, oxygen gas containing at least 10 wt. % of O₃ (Cp stands for cyclopentadienyl)
Ta₂O₃: Ta(OC₂H₅)₅, oxygen gas containing at least 10 wt. % of O₃
MgO: Mg(thd)₂, O₃ (thd stands for 2,2,6,6-tetramethyl-3,5-heptanedionate)
ZrO₂: ZrCp₂Cl₂, O₃
Nb₂O₃: Nb(OEt)₅, H₂O
CeO₂: Ce(thd)₄, O₃
Nd₂O₃: Nd(thd)₃, O₃
Sm₂O₃: Sm(thd)₃, O₃
Eu₂O₃: Eu(thd)₃, O₃
Ga₂O₃: Ga(acac)₃, O₃ (acac stands for acetylacetonate)
Dy₂O₃: Dy(thd)₃, O₃
Ho₂O₃: Ho(thd)₃, O₃
Er₂O₃: Er(thd)₃, O₃
Tm₂O₃: Tm(thd)₃, O₃
SiO₂: SiCl₂H₂, H₂O

Incidentally, where a stacked film is used as the gate insulating film 5, it suffices to form a film of the above-mentioned oxide material as a film constituting an uppermost layer of the stacked film.

Next, as shown in FIG. 2C, an oxide semiconductor layer 7 having an amorphous oxide containing at least one element selected from among Al, Ga, In, Zn, Mg, Ca, Sn, and Sb is formed in a pattern on the gate insulating film 5 formed using the oxide material. In this case, first, a film having the amorphous oxide is formed. Formation of the film having the amorphous oxide is conducted, for example, as follows.

In an exemplary method, where an amorphous InZnO thin film is to be formed, sputtering is conducted in which the sputtering target composition and the film forming conditions are optimized so that the atomic compositional ratio of In/Zn will be in the range of from 1.0 to 3.0. By this method, an amorphous InZnO thin film having a thickness of 50 nm is formed. In this case, the film forming conditions are desirably so set that the pressure of gaseous mixture of argon and oxygen is in the range of 0.1 to 10 Pa, and the partial pressure of oxygen is in the range of 1 to 10%. In the amorphous InZnO thin film, at least one element selected from among Mg, Y, Hf, Zr, Ta, Nb, and Ir may be contained in an amount of 0.5 to 10 at. %, for stabilizing the oxygen in the thin film.

In another exemplary method, where an amorphous InGaZnO thin film is to be formed, sputtering in which the sputtering target composition and the film forming conditions are optimized so that the atomic compositional ratio of In/Ga will be in the range of from 0.5 to 1.5, that of In/Zn from 0.5 to 2.5, and that of Ga/Zn from 1.0 to 2.0. By this method, an amorphous InGaZnO thin film having a thickness of 80 nm is formed. In this case, the film forming conditions are desirably so set that the pressure of gaseous mixture of argon and oxygen is in the range of 0.1 to 10 Pa, and the partial pressure of oxygen is in the range of 1 to 20%. In the amorphous InGaZnO thin film, at least one element selected from among Mg, Y, Hf, Zr, Ta, Nb, and Ir may be contained in an amount of 0.5 to 10 at. %, for stabilizing the oxygen in the thin film.

After the film of the amorphous oxide is formed as above, a resist pattern is formed on the amorphous oxide film by lithography, and, by using the resist pattern as a mask, the amorphous oxide film is etched in a pattern. As a result, an oxide semiconductor layer 7 having the amorphous oxide is formed in a pattern. The pattern etching of the film having the amorphous oxide may be dry etching such as RIE or may be wet etching.

As shown in FIG. 2D, a source electrode 9s and a drain electrode 9d are formed in patterns over the gate insulating film 5 provided thereon with the oxide semiconductor layer 7. In this case, first, an electrode forming layer of which the portion in contact with the oxide semiconductor layer 7 has at least one of iridium (Ir) and iridium oxide (IrO₂) is formed. Formation of the electrode forming layer is conducted, for example, as follows.

In an exemplary method, in forming the electrode forming layer, component layers of a stacked film of Cu (100 nm)/Ti (10 nm)/Ir (50 nm)/IrO₂ (30 nm) are formed by sputtering, sequentially from the IrO₂ layer. The film of IrO₂ is desirably formed in the conditions such that the pressure of gaseous mixture of argon and oxygen is in the range of 0.1 to 10 Pa, and the partial pressure of oxygen is in the range of 1 to 20%. Incidentally, for preventing diffusion of oxygen, the thickness of the Ir layer is desirably not less than 5 nm.

In another exemplary method, in forming the electrode forming layer, component layers of a stack film of Cu (100 nm)/Ti (10 nm)/Ir (50 nm) are formed by sputtering, sequentially from the Ir layer. Incidentally, the thickness of the Ir layer is desirably not less than 5 nm, for preventing diffusion of oxygen.

After the electrode forming layer is formed in this manner, a resist pattern is formed on the electrode forming layer by lithography, and, using the resist pattern as a mask, the electrode forming layer is etched in patterns. By this, a source electrode 9s and a drain electrode 9d of which the lowermost layer in contact with the oxide semiconductor layer 7 has at least one of iridium (Ir) and iridium oxide (IrO₂) are formed in patterns. The pattern etching of the electrode forming layer may be dry etching such as RIE or may be wet etching.

Thereafter, as has been shown in FIG. 1, an insulating film 11 having the above-mentioned oxide material is formed over the gate insulating film 5 provided thereover with the source electrode 9s and the drain electrode 9d. The film having the oxide material constituting the insulating film 11 is formed in a manner similar to that for forming the gate insulating film 5. Thus, the method of forming the insulating film 11 is not particularly limited; for example, plasma enhanced CVD, sputtering, ALD or the like may be employed.

Incidentally, where a stack film is used as the insulating film 11, it suffices to form a film composed as the above-mentioned oxide material as a film constituting the lowermost layer in contact with the oxide semiconductor layer 7.

After the insulating film 11 is formed as above, an oxidizing treatment is conducted in an oxygen atmosphere containing 5 to 30 wt. % of ozone, whereby oxygen defects in the oxide semiconductor layer 7 and the gate insulating film 5 are eliminated. Here, in the case where a substrate of a material having good heat resistance such as a glass substrate and a metallic foil substrate is used as the substrate 1, an oxidizing treatment is conducted in a temperature range of 150 to 450° C. for about an hour. On the other hand, where a substrate of a material having comparatively low heat resistance such as a plastic substrate is used, an oxidizing treatment is carried out in a temperature range of 50 to 100° C. for about an hour.

In this manner, a thin film transistor Tr1 can be obtained which is optimum for use as a driving transistor in liquid crystal displays and organic EL displays and in which long-term stability of transistor characteristics is attained, as has been described referring to FIG. 1 above.

### Modification of First Embodiment

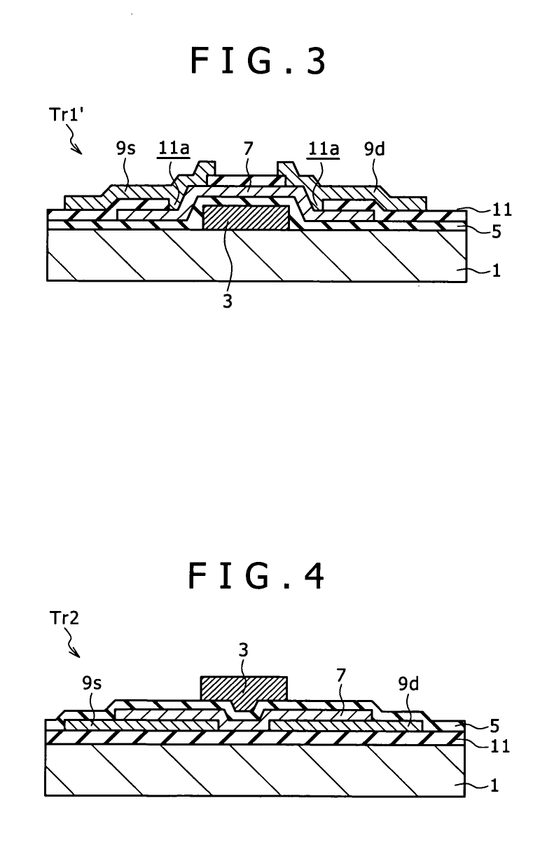

A thin film transistor Tr1′ shown in FIG. 3 is a modification of the bottom-gate thin film transistor described in the first embodiment above. The thin film transistor Tr1′ of the modification shown in FIG. 3 differs from the thin film transistor Tr1 shown of FIG. 1 in the order of stacking of the insulating film 11 covering the oxide semiconductor layer 7 and the source and drain electrodes 9s and 9d. Therefore, the components equivalent to those described above are denoted by the same reference symbols used above, and descriptions of them will be omitted.

A gate electrode 3 is formed in a pattern on a substrate 1, and a gate insulating film 5 having an oxide material is provided so as to cover the gate electrode 3. On the gate insulating film 5, a semiconductor layer 7 having an amorphous oxide (hereinafter referred to as oxide semiconductor layer) is provided on the upper side of the gate electrode 3. Besides, an insulating film 11 having an oxide material is provided in the state of covering the oxide semiconductor layer 7. The insulating film 11 is provided with two apertures 11a that reaches the oxide semiconductor layer 7 at both lateral sides of the gate electrode 3. Over the insulating film 11, a source electrode 9s and a drain electrode 9d formed by use of iridium or iridium oxide are provided in the state of making contact with the oxide semiconductor layer 7 at the apertures 11a.

As a result, the oxide semiconductor layer 7 is covered by the source electrode 9s and the drain electrode 9d formed using iridium (Ir) or iridium oxide (IrO₂) and the gate insulating film 5 and the insulating film 11 which are each formed using an oxide material.

Here, like in the first embodiment above, each of the gate insulating film 5 and the insulating film 11 may have a stacked structure or a monolayer structure insofar as at least an interface layer thereof on the side of contact with the oxide semiconductor layer 7 has an oxide material. In addition, like in the first embodiment, each of the source electrode 9s and the drain electrode 9d preferably has a structure in which the portion in contact with the oxide semiconductor layer 7 has a layer including iridium (Ir) or iridium oxide (IrO₂) and a layer having a highly conductive material is stacked on the layer having iridium (Ir) or iridium oxide (IrO₂).

In the thin film transistor Tr1′ thus configured, also, the oxide semiconductor layer 7 is covered by the source electrode 9s and the drain electrode 9d composed using iridium (Ir) or iridium oxide (IrO₂) and the gate insulating film 5 and the insulating film 11 which are each formed using an oxide material. Therefore, effects similar to those of the thin film transistor Tr1 in the first embodiment above can be obtained. Specifically, diffusion of reducing atoms or molecules such as those of hydrogen and nitrogen into the oxide semiconductor layer 7 and losing of oxygen from the oxide semiconductor layer 7 through diffusion can be prevented, and, therefore, stabilization of characteristics of the thin film transistor Tr1′ for a long time can be achieved. In addition, the source electrode 9s and the drain electrode 9d formed using iridium (Ir) or iridium oxide (IrO₂) have good adhesion to the amorphous oxide constituting the oxide semiconductor layer 7, and, accordingly, film exfoliation due to internal stress can be prevented from occurring.

Incidentally, the thin film transistor Tr1′ according to the modification can be manufactured through changing the sequence of the manufacturing steps described in the first embodiment above. Specifically, it suffices to sequentially carry out a step of forming the oxide semiconductor layer 7 in a pattern, a step of forming the insulating film 11, an additional step of providing the insulating film 11 with the apertures 11a, and a step of forming the source electrode 9s and the drain electrode 9d in patterns. The details of each manufacturing step are the same as those described in the first embodiment above. Besides, the additional step of providing the insulating film 11 with the apertures 11a may be carried out by etching the insulating film 11 while using a lithographically formed resist pattern as a mask.

### 2. Second Embodiment

### <Configuration of Thin Film Transistor>

FIG. 4 is a sectional view of a thin film transistor Tr2 according to a second embodiment of the present invention. The thin film transistor Tr2 shown in the figure is a top-gate thin film transistor Tr2 in which a semiconductor layer having an amorphous oxide (oxide semiconductor layer) is used as an active layer, and which is configured as follows. Incidentally, the components the same as those in the first embodiment above are denoted by the same reference symbols as used above, and descriptions of these components will be omitted.

An insulating film 11 formed by use of an oxide material is provided on a substrate 1. Over the insulating film 11, a source electrode 9s and a drain electrode 9d are provided by use of iridium (Ir) or iridium oxide (IrO₂), and, further, an oxide semiconductor layer 7 having an amorphous oxide is provided between and partly on the source electrode 9s and the drain electrode 9d. In addition, a gate insulating film 5 having an oxide material is provided in the state of covering these components, and a gate electrode 3 is provided on the gate insulating film 5 on the upper side of the area between the source electrode 9s and the drain electrode 9d.

As a result, like in the first embodiment, the oxide semiconductor layer 7 is covered by the source electrode 9s and the drain electrode 9d formed using iridium or iridium oxide and the gate insulating film 5 and the insulating film 11 which are each formed using an oxide material.

Here, like in the first embodiment, the insulating film 11 and the gate insulating film 5 may each have a stacked structure or a monolayer structure insofar as at least an interface layer thereof on the side of contact with the oxide semiconductor layer 7 has an oxide material. Preferable examples of the oxide material used for forming the insulating film 11 and the gate insulating film 5 include Y₂O₃, Al₂O₃, Ta₂O₅, HfO₂, MgO, ZrO₂, Nb₂O₅, Sm₂O₃, Eu₂O₃, Ga₂O₃, Dy₂O₃, Ho₂O₃, Er₂O₃, Tm₂O₃, and SiO₂, like in the first embodiment above.

In addition, like in the first embodiment, each of the source electrode 9s and the drain electrode 9d preferably has a structure in which the portion in contact with the oxide semiconductor layer 7 has a layer having iridium (Ir) or iridium oxide (IrO₂) and a layer having a highly conductive material is stacked on the layer having iridium (Ir) or iridium oxide (IrO₂). Examples of the structure of the source electrode 9s and the drain electrode 9d are similar to those in the first embodiment. An example is a stacked structure of Cu (100 nm)/Ti (10 nm)/Ir (50 nm)/IrO₂ (30 nm) in this order from the lower side. Another example is a stacked structure of Cu (100 nm)/Ti (10 nm)/Ir (50 nm) in this order from the lower side. In these structures, for preventing diffusion of oxygen, the thickness of the Ir layer is desirably not less than 5 nm, like in the first embodiment above.

In the thin film transistor Tr2 configured as above, also, the oxide semiconductor layer 7 is covered by the source electrode 9s and the drain electrode 9d formed using iridium (Ir) or iridium oxide (IrO₂) and the gate insulating film 5 and the insulating film 11 which are each formed using an oxide material. Therefore, similar effects to those of the thin film transistor Tr1 in the first embodiment can be obtained. Specifically, diffusion of reducing atoms or molecules such as those of hydrogen and nitrogen into the oxide semiconductor layer 7 and losing of oxygen from the oxide semiconductor layer 7 through diffusion can be prevented, so that stabilization of characteristics of the thin film transistor Tr2 for a long period of time can be realized. In addition, since the source electrode 9s and the drain electrode 9d formed using iridium (Ir) or iridium oxide (IrO₂) have good adhesion with the amorphous oxide used to form the oxide semiconductor layer 7, film exfoliation due to internal stress can be prevented from occurring.

### <Manufacturing Method for Thin Film Transistor>

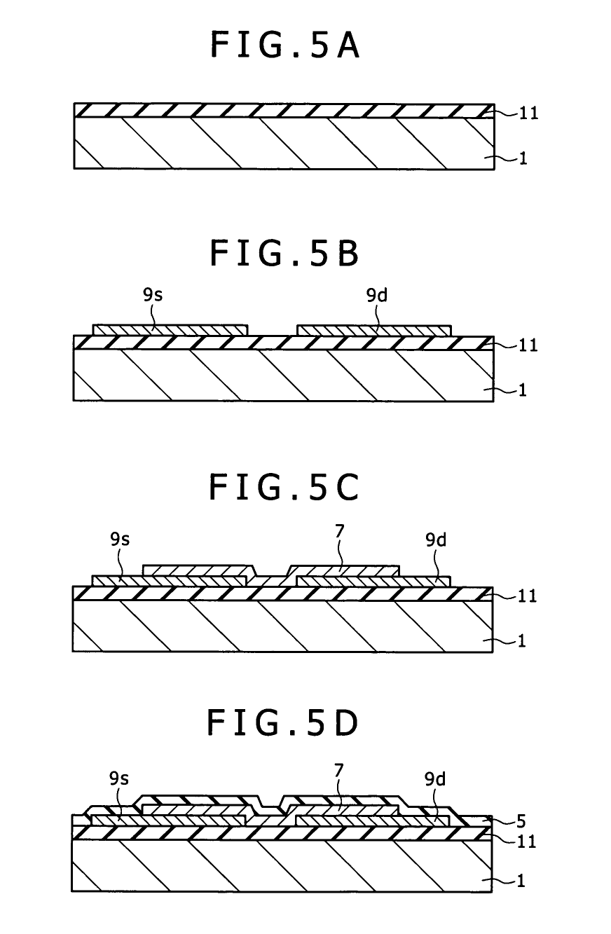

Now, a method of manufacturing the thin film transistor Tr2 according to the second embodiment will be described in detail below, referring to sectional manufacturing-step views shown in FIGS. 5A to 5D.

First, as shown in FIG. 5A, a substrate 1 which is insulating on the face side is prepared. The substrate 1 is for example similar to that in the first embodiment, and has a structure in which a silicon oxynitride film for preventing diffusion of hydrogen is formed in a thickness of 300 nm on a 1 mm-thick alkali-free glass substrate, plastic substrate or stainless steel substrate. The method of forming the silicon oxynitride film is not particularly limited; for example, plasma CVD, sputtering and the like are applicable.

Next, the insulating film 11 having the above-mentioned oxide material is formed on the substrate 1. Like in the first embodiment, the method of forming the insulating film 11 is not particularly limited; for example, plasma enhanced CVD, sputtering, ALD or the like may be used. In an example, an insulating film 11 having aluminum oxide is formed in a thickness of 100 nm. Incidentally, where a stacked film is used as the insulating film 11, it suffices that a film having the above-mentioned oxide material is formed as a film constituting an uppermost layer of the stacked film.

Subsequently, as shown in FIG. 5B, a source electrode 9s and a drain electrode 9d are formed in respective patterns on the insulating film 11. Here, first, an electrode forming layer of which the portion to be put into contact with the oxide semiconductor layer 7 has at least one of iridium (Ir) or iridium oxide (IrO₂) is formed. Formation of such an electrode forming layer is conducted, for example, as follows.

In an exemplary method of forming the electrode forming layer, component layers of a stacked film of Ir (100 nm)/Ti (10 nm) are formed by sputtering, sequentially from the Ti layer. Incidentally, the thickness of the Ir layer is desirably not less than 5 nm, for preventing diffusion of oxygen.

In another exemplary method of forming the electrode forming layer, component layers of a stacked film of IrO₂ (30 nm)/Ir (100 nm)/Ti (10 nm) are formed by sputtering, sequentially from the Ti layer. Incidentally, the thickness of the Ir layer is desirably not less than 5 nm, for preventing diffusion of oxygen.

After the electrode forming layer is thus formed, a resist pattern is formed on the electrode forming layer by lithography, and, by using the resist pattern as a mask, the electrode forming layer is subjected to pattern etching. By this, the source electrode 9s and the drain electrode 9d of which at least an uppermost layer has at least one of iridium (Ir) and iridium oxide (IrO₂) are formed in respective patterns. The pattern etching of the electrode forming layer may be dry etching such as RIE or may be wet etching.

Thereafter, as shown in FIG. 5C, the oxide semiconductor layer 7 having an amorphous oxide containing at least one element selected from among Al, Ga, In, Zn, Mg, Ca, Sn, and Sb is formed in a pattern. In this case, first, a film having the amorphous oxide is formed. Formation of the film having the amorphous oxide is carried out similarly to that in the first embodiment.

For instance, where an amorphous InZnO thin film is to be formed, a sputtering is conducted in which the sputtering target compositions and the film forming conditions are optimized so that the atomic compositional ratio of In/Zn will be in the range of from 1.0 to 3.0, whereby a 50 nm-thick amorphous InZnO thin film is formed. On the other hand, where an amorphous InGaZnO thin film is to be formed, a sputtering is carried out in which the sputtering target atomic compositions and the film forming conditions are optimized so that the atomic compositional ratio of In/Ga will be in the range of from 0.5 to 1.5, that of In/Zn in the range of from 0.5 to 2.5, and Ga/Zn in the range of from 1.0 to 2.0, whereby a 80 nm-thick amorphous InGaZnO thin film is formed. Incidentally, in each of the amrohpus InZnO thin film and the amorphous InGaZnO film, at least one element selected from among Mg, Y, Hf, Zr, Ta, Nb, and Ir may be contained in an amount of 0.5 to 10 at. %, for stabilizing the oxygen in the thin film.

After the film having the amorphous oxide is formed as above, a resist pattern is formed on the amorphous oxide film by lithography. Then, by using the resist pattern as a mask, the amorphous oxide film is subjected to pattern etching, whereby the oxide semiconductor layer 7 having the amorphous oxide is patterned. The pattern etching of the amorphous oxide film may be dry etching such as RIE or may be wet etching.

Thereafter, as shown in FIG. 5D, a gate insulating film 5 having the above-mentioned oxide material is formed over the insulating film 11 provided thereon with the source electrode 9s and the drain electrode 9d and further with the oxide semiconductor layer 7. Formation of the oxide material layer for constituting the gate insulating film 5 is conducted similarly to that in the first embodiment, and the method of forming the gate insulating film 5 is not particularly limited; for example, plasma enhanced CVD, sputtering, ALD or the like may be used.

Incidentally, where a stacked film is used as the gate insulating film 5, it suffices that a film having the above-mentioned oxide material is formed as a lowermost layer in contact with the oxide semiconductor layer 7.

In addition, after the gate insulating film 5 is formed as above, an oxidizing treatment is conducted in an oxygen atmosphere containing 5 to 30 wt. % of ozone, whereby oxygen defects in the oxide semiconductor layer 7 and the gate insulating film 5 are eliminated. Here, in the case where a substrate of a material having good heat resistance such as a glass substrate, a metallic foil substrate, etc. is used as the substrate 1, the oxidizing treatment is carried out in a temperature range of 150 to 450° C. for about an hour. On the other hand, where a substrate of a material having comparatively low heat resistance such as a plastic substrate is used as the substrate 1, the oxidizing treatment is conducted in a temperature range of 50 to 100° C. for about an hour.

Thereafter, as shown in FIG. 4 above, a gate electrode 3 is formed in a pattern on the gate insulating film 5. In this case, for example, component layers of a stacked film of Al (100 nm)/Ti (10 nm) are formed by sputtering, sequentially from the Ti layer. Thereafter, a resist pattern is formed on the stacked film by photolithography, and, using the resist pattern as a mask, pattern etching of the stacked film is conducted, to obtain the gate electrode 3. The pattern etching of the stacked film may be dry etching such as RIE or may be wet etching.

In this way, the thin film transistor Tr2 can be obtained which is optimum for use as a driving transistor in liquid crystal displays and organic EL displays and in which stabilization of transistor characteristics for a long time is realized, as has been described referring to FIG. 4 above.

### 3. Third Embodiment

### <Sectional Configuration of Liquid Crystal Display>

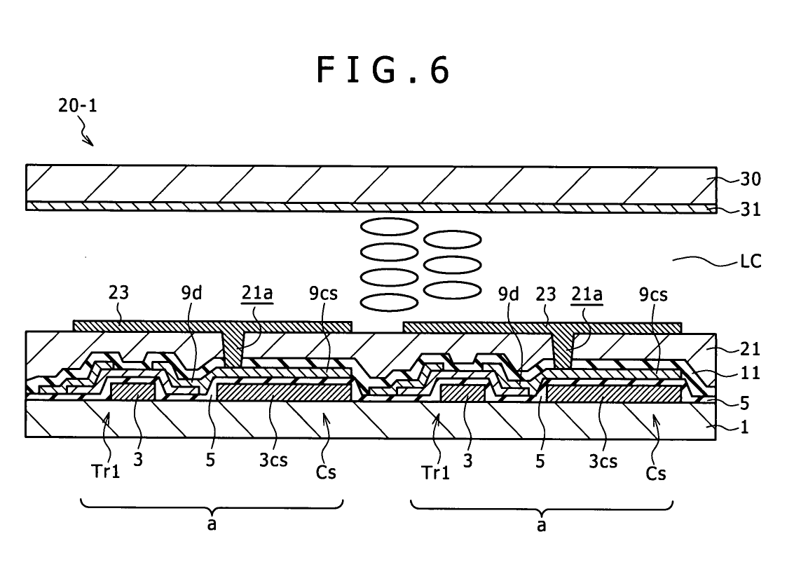

FIG. 6 is a schematic sectional diagram, corresponding to two pixels, of a liquid crystal display 20-1 in which the bottom-gate thin film transistor Tr1 described in the first embodiment above is used. The liquid crystal display 20-1 according to this third embodiment of the present invention as shown in the figure has a configuration in which a substrate 1 provided thereon with the thin film transistors Tr1 of the first embodiment is used as a driving-side substrate, and a liquid crystal layer LC is sandwiched between the driving-side substrate 1 and an opposite substrate 30.

Of these components, the driving-side substrate 1 is configured as follows.

Each of pixels a on the driving-side substrate 1 has the thin film transistor Tr1 of the first embodiment and, also, a capacitance element Cs connected thereto. While the thin film transistor Tr1 of the first embodiment described above referring to FIG. 1 is shown here as an example of the thin film transistor, the thin film transistor may be the thin film transistor Tr1′ according to the modification of the first embodiment. The capacitance element Cs has a first electrode 3cs having the same layer as the gate electrode 3 of the thin film transistor Tr1, and a second electrode 9cs formed by extending the drain electrode 9d of the thin film transistor Tr1, with the gate insulating film 5 sandwiched between the first and second electrodes 3cs and 9cs.

The insulating film 11 having an oxide material is provided in the state of covering the thin film transistors Tr1 and the capacitance elements Cs configured as above, and an interlayer dielectric 21 is provided on the insulating film 11. The interlayer dielectric 21 is provided, for example, as a flattening insulating film, and is provided with connection holes 21a reaching the drain electrodes 9d of the thin film transistors Tr1, respectively. On the interlayer dielectric 21, pixel electrodes 23 are formed in an array in the state of being each connected to the capacitance element Cs and the thin film transistor Tr1 through the connection hole 21a. The pixel electrodes 23 are composed of a reflective material, for example.

On the other hand, the opposite substrate 30 is configured as follows.

The opposite substrate 30 is not particularly limited in regard of material, insofar as it is formed by use of a light-transmitting material and an insulating property is maintained on the face side thereof. For example, a plastic substrate or a glass substrate, or a substrate obtained by providing an insulating film on a surface of a metallic foil substrate so thin as to permit light to be transmitted therethrough, may be used. In addition, where the liquid crystal display 20-1 is requested to have flexible bending properties, a plastic substrate or an insulator-coated metallic foil substrate may be used preferably.

The opposite substrate 30 is provided with a counter electrode 31 on its surface facing the driving-side substrate 1. The counter electrode 31 is a common electrode which serves in common for the pixels, and is formed by use of a transparent electrode material having a light-transmitting property such as ITO. Such a counter electrode 31 may be provided in a solid form on the opposite substrate 30.

### <Circuit Configuration of Liquid Crystal Display>

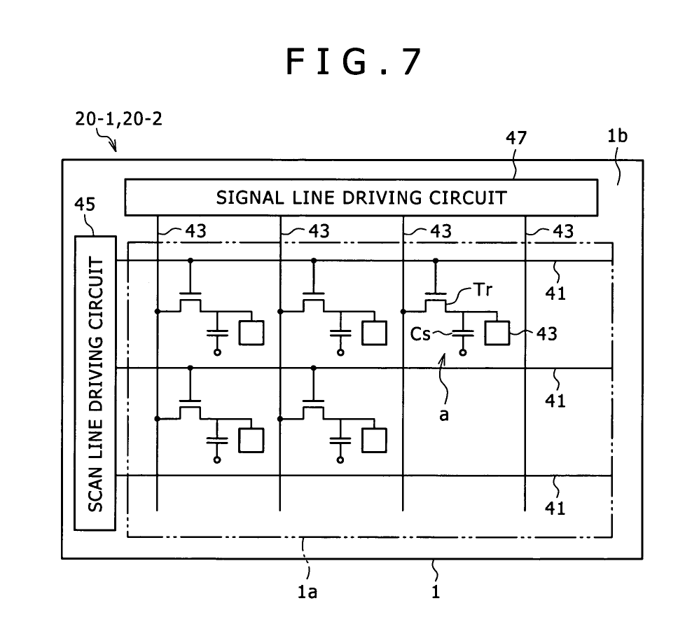

FIG. 7 illustrates an example of circuit configuration of the liquid crystal display 20-1.

As shown in the figure, a display region 1a and a peripheral region 1b are set on the driving-side substrate 1 of the liquid crystal display 20-1. The display region 1a is configured as a pixel array section in which a plurality of scan lines 41 and a plurality of signal lines 43 are arranged in row and column directions, and one pixel a is provided correspondingly to each of intersections of the scan and signal lines 41 and 43. In addition, a scan line driving circuit 45 for driving the scan lines 41 in a scanning manner and a signal line driving circuit 47 for supplying the signal lines 43 with video signals (namely, input signals) according to luminance data are arranged in the peripheral region 1b.

At each of the intersections of the scan lines 41 and the signal lines 43, a pixel circuit having a thin film transistor Tr and a capacitance element Cs is provided. The thin film transistor Tr has its gate electrode connected to the scan line 41, and has its source electrode connected to the signal line 43. In addition, the drain electrode of the thin film transistor Tr is connected to the second electrode of the capacitance element Cs and the pixel electrode 23. Besides, the first electrode of the capacitance element Cs is connected to a common wiring. The third embodiment is characterized in that the thin film transistor Tr has the thin film transistor Tr1 (Tr1′) according to the first embodiment.

Under driving by the scan line driving circuit 45, a video signal written from the signal line 41 through the thin film transistor Tr is held in the capacitance element Cs, and a voltage according to the amount of signal thus held is supplied to the pixel electrode 23. As a result, according to the voltages supplied to the pixel electrodes 23, liquid crystal molecules m constituting the liquid crystal layer LC shown in FIG. 6 are tilted, whereby transmission of display light is controlled.

The configuration of the pixel circuit as above is merely an example; thus, capacitance elements may be provided in the pixel circuit as required, or a plurality of transistors may be provided in each pixel circuit. Besides, according to modifications made in the pixel circuit, driving circuits newly required are added to the peripheral region 1b.

In the liquid crystal display 20-1 thus configured, the pixel electrode 23 is driven by the thin film transistor Tr1 (Tr1′) described in the first embodiment above. The thin film transistor Tr1 (Tr1′) has a threshold voltage controlled in the range of 2 to 10 V with good reproducibility, and a source-drain current (Ids) at a value of 1.0×10⁻⁴ to 2.0×10⁻³ A. Therefore, the thin film transistor Tr1 (Tr1′) is optimum for driving the liquid crystal display 20-1. In addition, the thin film transistor Tr1 (Tr1′) has been improved to show stable transistor characteristics for a long time, as described in the first embodiment above. Accordingly, it is possible to enhance long-term reliability of display characteristics of the liquid crystal display 20-1.

### 4. Fourth Embodiment

### <Sectional Configuration of Liquid Crystal Display>

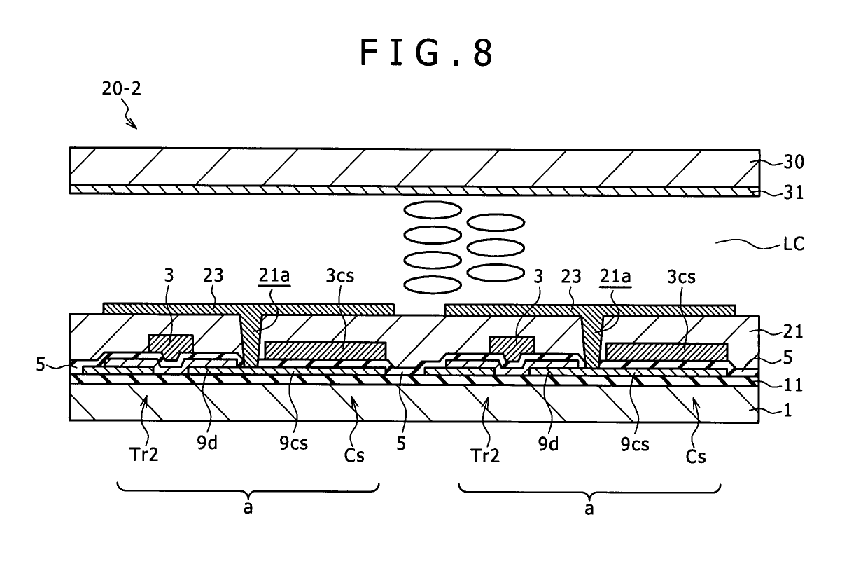

FIG. 8 is a schematic sectional diagram, for two pixels, of a liquid crystal display 20-2 in which the top-gate thin film transistor Tr2 described in the second embodiment above is used. The liquid crystal display 20-2 in the fourth embodiment shown in the figure differs from the liquid crystal display 20-1 of the third embodiment in that the thin film transistor Tr2 according to the second embodiment is used as the thin film transistor to be connected to a pixel electrode 23.

Specifically, each of pixels a on the driving-side substrate 1 is provided with the thin film transistor Tr2 of the second embodiment and, also, with a capacitance element Cs connected to the thin film transistor Tr2. The capacitance element Cs has a first electrode 3cs having the same layer as the gate electrode 3 of the thin film transistor Tr1, and a second electrode 9cs formed by extending the drain electrode 9d of the thin film transistor Tr1, with the gate insulating film 5 sandwiched between the first and second electrodes 3cs and 9cs.

An interlayer dielectric 21, provided so as to cover the thin film transistors Tr and the capacitance elements Cs, and the gate insulating film 5 are provided with connection holes 21a respectively reaching the drain electrodes 9d of the thin film transistors Tr2. On the interlayer dielectric 21, an array of pixel electrodes 23 are formed each of which is connected to the capacitance element Cs and the thin film transistor Tr2 through the connection hole 21a.

On the other hand, the configuration of an opposite substrate 30 is similar to that in the third embodiment, and a counter electrode 31 is provided on that surface of the opposite substrate 30 formed by using a light-transmitting material which faces the driving-side substrate 1. The counter electrode 31 is a common electrode which serves in common for the pixels, and is formed by use of a transparent electrode material having a light-transmitting property such as ITO. Such a counter electrode 31 may be provided in a solid form on the opposite substrate 30.

### <Circuit Configuration of Liquid Crystal Display>

The circuit configuration of the liquid crystal display 20-2 according to the fourth embodiment is similar to that in the third embodiment. It is characteristic in that the top-gate thin film transistor Tr2 in the second embodiment is used as a thin film transistor shown in FIG. 7.

In the liquid crystal display 20-2 thus configured, the pixel electrode 23 is driven by the thin film transistor Tr2 described in the second embodiment above. The thin film transistor Tr2 has a threshold voltage controlled in the range of 2 to 10 V with good reproducibility, and has a source-drain current (Ids) at a value of 1.0×10⁻⁴ to 2.0×10⁻³ A. Therefore, the thin film transistor Tr2 is optimum for driving the liquid crystal display 20-2. In addition, like the thin film transistor Tr1 of the first embodiment, this thin film transistor Tr2 also has been improved to show stable transistor characteristics for a long time. Accordingly, it is possible to enhance long-term reliability of display characteristics of the liquid crystal display 20-2 manufactured using the thin film transistor Tr2.

### 5. Fifth Embodiment

### <Sectional Configuration of Organic EL Display>

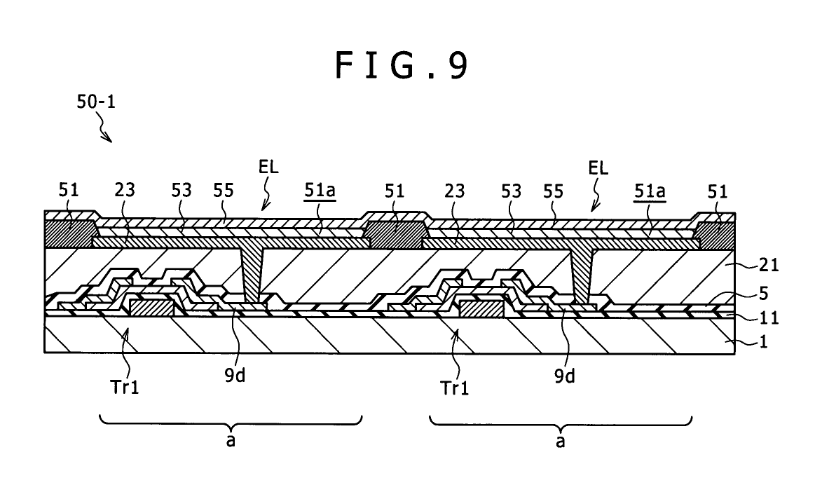

FIG. 9 is a schematic sectional diagram, for two pixels, of an organic EL display 50-1 configured by using the bottom-gate thin film transistor Tr1 described in the first embodiment above. The organic EL display 50-1 according to this fifth embodiment shown in the figure has a configuration in which a substrate 1 provided thereon with the thin film transistors Tr1 of the first embodiment is used as a driving-side substrate, and an organic electroluminescence (EL) elements EL are provided on the driving-side substrate 1.

Each of pixels a on the driving-side substrate 1 has two thin film transistors Tr1 (in the drawing, one thin film transistor Tr1 is shown) according to the first embodiment, and a capacitance element Cs which is omitted in the drawing. While the thin film transistor Tr1 of the first embodiment described referring to FIG. 1 above is shown as an example of the thin film transistor here, the thin film transistor may be the thin film transistor Tr1′ according to the modification of the first embodiment.

An insulating film 11 is provided in the state of covering the thin film transistors Tr1 as above, and an interlayer dielectric 21 is provided further over the insulating film 11. The interlayer dielectric 21 is provided, for example, as a flattening insulating film, and is provided with connection holes 21a respectively reaching the drain electrodes 9d of the thin film transistors Tr1. On the interlayer dielectric 21, an array of pixel electrodes 23 are formed which are each connected to the thin film transistor Tr1 through the connection hole 21a.

The pixel electrodes 23 are configured, for example, as anodes or cathodes. Where the organic EL display 50-1 is of the top emission structure in which display light is emitted from the side opposite to the driving-side substrate 1, the pixel electrodes 23 are formed by use of a light-reflective material.

The periphery of the pixel electrode 23 is covered with an insulating pattern 51 for isolation of the organic electroluminescence element EL. The insulating pattern 51 is provided with an open window 51a for widely exposing the pixel electrode 23, and the open window 51a constitutes a pixel aperture of the organic electroluminescence element EL.

An organic layer 53 is provided in the state of covering the upper side of the pixel electrode 23 exposed in the open window 51a in the insulating pattern 51. The organic layer 53 has a stacked structure including at least an organic light emitting layer. A common electrode 55 is provided in the state of covering the organic layers 53 and sandwiching the organic layers 53 between itself and the pixel electrodes 23, respectively. The common electrode 55 is an electrode on the side on which light h generated in the organic light emitting layer of the organic electroluminescence element EL is taken out. The common electrode 55 is formed by use of a light-transmitting material. In addition, where the pixel electrodes 23 function as anodes, the common electrode 55 is formed by use of a material which functions as cathode.

Each pixel portion in which the organic layer 53 is sandwiched between the pixel electrode 23 and the common electrode 55 in this manner functions as the organic electroluminescence element EL.

Besides, while omitted in the drawing here, the organic EL display 50-1 has a configuration in which its side of formation of the organic electroluminescence elements EL is covered with a sealing resin having a light-transmitting material, and an opposite substrate having a light-transmitting material is laminated on this side through the sealing resin therebetween.

### <Circuit Configuration of Organic EL Display>

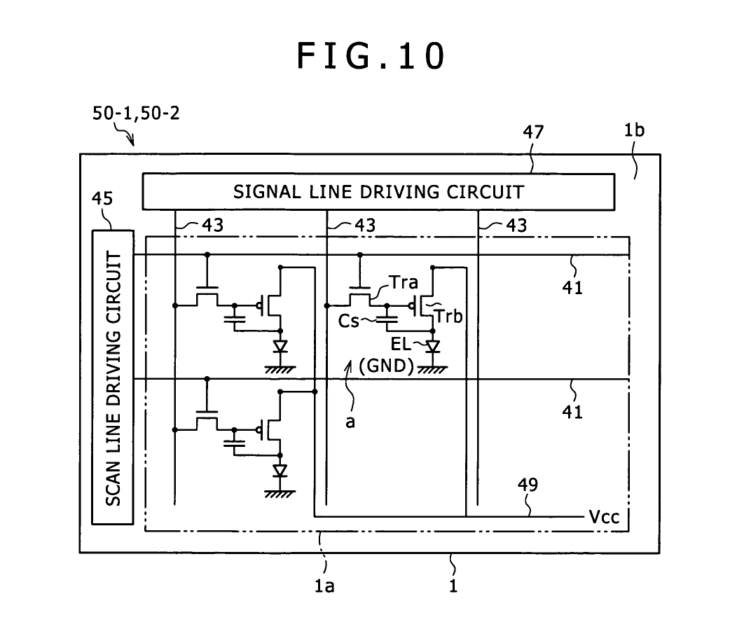

FIG. 10 illustrates a circuit configuration of the organic EL display 50-1.

As shown in the figure, on the driving-side substrate 1 of the organic EL display 50-1, a display region 1a and a peripheral region 1b are set. The display region 1a is configured as a pixel array section in which a plurality of scan lines 41 and a plurality of signal lines 43 are arranged in row and column directions, and one pixel a is provided at each of intersections of the scan lines 41 and the signal lines 43. Besides, in the peripheral region 1b, a scan line driving circuit 45 for driving the scan lines 41 in a scanning manner and a signal line driving circuit 47 for supplying the signal lines 43 with video signals (namely, input signals) according to luminance data are arranged.

A pixel circuit provided at each intersection of the scan line 41 and the signal line 43 has, for example, a thin film transistor Tra for switching, a thin film transistor Trb for driving, a capacitance element Cs, and an organic electroluminescence element EL. Under driving by the scan line driving circuit 35, a video signal written from the signal line 33 through the switching thin film transistor Tra is held in the capacitance element Cs, a current according to the amount of signal thus held is supplied to the organic electroluminescence element EL from the driving thin film transistor Trb, and the organic electroluminescence element EL emit light at a luminance according to the current. Incidentally, the driving thin film transistors Trb are connected to a common power supply line (Vcc) 49.

The sectional view in FIG. 9 shows a section of that portion of the pixel circuit as above-mentioned in which the driving thin film transistor Trb and the organic electroluminescence element EL are stacked. The thin film transistor Tra shown in the pixel circuit is configured by use of the same layer as that used for the thin film transistor Trb, and these thin film transistors Tra and Trb are composed by use of the thin film transistors Tr1 (Tr1′) according to the first embodiment described referring to FIG. 1 above.

Incidentally, the capacitance element Cs shown in the pixel circuit is configured by stacking the gate electrode-gate insulating film-drain electrode layer portions of the thin film transistor Tr1. Further, the scan lines 41 shown in the pixel circuit are configured by use of the same layer as that used for the gate electrodes 11 in the sectional figure, and the signal lines 43 and the power supply line 49 shown in the pixel circuit are configured by use of the same layer as that used for the source electrodes 15s and the drain electrodes 15d in the sectional view.

The configuration of the pixel circuit as above is merely an example. Thus, the pixel circuit may be configured by providing the capacitance elements in the pixel circuit as required, or further providing a plurality of transistors in the pixel circuit. Besides, according to the modifications made in the pixel circuit, driving circuits newly required are added to the peripheral region 1b.

In the organic EL display 50-1 configured as above, the pixel electrodes 23 are driven by the thin film transistors Tr1 (Tr1′) described in the first embodiment above. The thin film transistor Tr1 (Tr1′) has a threshold voltage controlled in the range of 2 to 10 V with good reproducibility, and a source-drain current (Ids) at a value of 1.0×10⁻⁴ to 2.0×10⁻³ A. Therefore, the thin film transistor Tr1 (Tr1′) is optimum for driving the organic EL display 50-1. In addition, the thin film transistor Tr1 (Tr1′) has been improved to show stabilized transistor characteristics for a long time, as has been described in the first embodiment above. Accordingly, it is possible to enhance long-term reliability of display characteristics of the organic EL display 50-1.

### 6. Sixth Embodiment

### <Sectional Configuration of Organic EL Display>

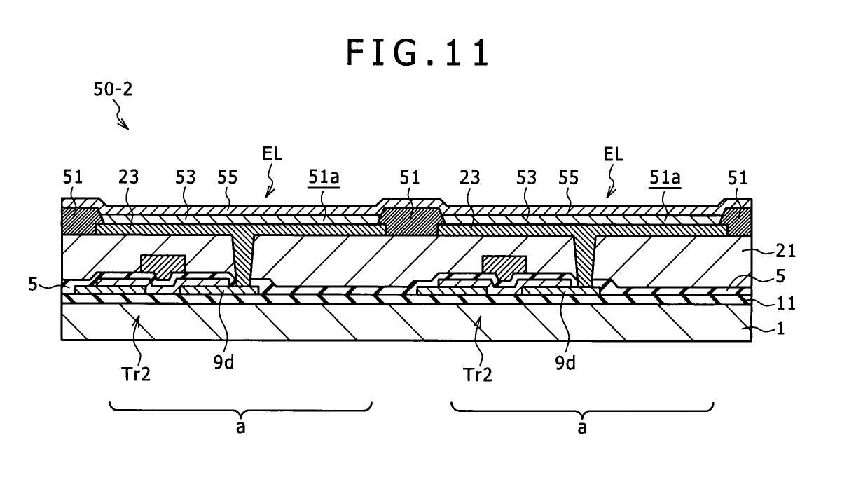

FIG. 11 is a schematic sectional diagram, for two pixels, of an organic EL display 50-2 configured by use of the top-gate thin film transistor Tr2 described in the second embodiment above. The organic EL display 50-2 according to this sixth embodiment shown in the figure differs from the organic EL display 50-1 of the fifth embodiment in that the thin film transistor Tr2 according to the second embodiment is used as the thin film transistor in each pixel a.

Specifically, each of the pixels a on a driving-side substrate 1 has the thin film transistor Tr2 according to the second embodiment above and, also, a capacitance element Cs (omitted in the drawing) connected to the thin film transistor Tr2.

An interlayer dielectric 21 and a gate insulating film 5 which are provided in the state of covering the thin film transistors Tr2 and the capacitance elements Cs are provided with connection holes 21a respectively reaching the drain electrodes 9d of the thin film transistors Tr2. An array of pixel electrodes 23 each connected to the thin film transistor Tr2 through the connection hole 21a are formed on the interlayer dielectric 21. The pixel electrodes 23 are configured as anodes or cathodes.

The periphery of each of the pixel electrodes 23 is covered with an insulating pattern 51, an organic layer 53 having at least an organic light emitting layer is provided in the state of covering the upper side of the pixel electrode 23 exposed from the insulating pattern 51, and a common electrode 55 is provided in the state of sandwiching the organic layers 53 between itself and the pixel electrodes 23, respectively. The common electrode 55 is an electrode on the side on which the light h generated in the organic light emitting layer of the organic electroluminescence element EL is taken out. The common electrode 55 is formed by use of a light-transmitting material. Further, where the pixel electrodes 23 function as anodes, the common electrode 55 is configured by use of a material which functions as cathode.

In addition, that pixel portion in which the organic layer 53 is sandwiched between the pixel electrode 23 and the common electrode 55 functions as the organic electroluminescence element EL.

### <Circuit Configuration of Organic EL Display>

The circuit configuration of the organic EL display 50-2 according to the sixth embodiment is similar to that in the fifth embodiment, and the top-gate thin film transistor Tr2 according to the second embodiment is used as each of the thin film transistors Tra and Trb shown in FIG. 10.

In the organic EL display 50-2 thus configured, the pixel electrode 23 is driven by the thin film transistor Tr2 described in the second embodiment above. The thin film transistor Tr2 has a threshold voltage controlled in the range of 2 to 10 V with good reproducibility, and a source-drain current (Ids) showing a value of 1.0×10⁻⁴ to 2.0×10⁻³ A. Therefore, the thin film transistor Tr2 is optimum for driving the organic EL display 50-2. Besides, like the thin film transistor Tr1 of the first embodiment, this thin film transistor Tr2 also has been improved to show stable transistor characteristics for a long time. Accordingly, it is possible to enhance long-term reliability of display characteristics of the organic EL display 50-2.

In the third to sixth embodiments above, liquid crystal displays and organic EL displays have been shown as displays according to embodiments of the present invention. However, the display pertaining to the present invention is widely applicable to displays in which the thin film transistors according to the first embodiment or the second embodiment are provided, especially, to active matrix type displays in which pixel electrodes are driven by these thin film transistors. More specifically, for example, the display pertaining to the invention is applicable to electrophoresis type displays. Besides, the configurations of the liquid crystal displays and the organic EL displays are not limited to those according to the third to sixth embodiments described above. The configurations are widely applicable to those in which pixel electrodes are driven by thin film transistors according to the first embodiment or the second embodiment, and similar effects to the above-mentioned can be obtained.

### 7. Seventh Embodiment

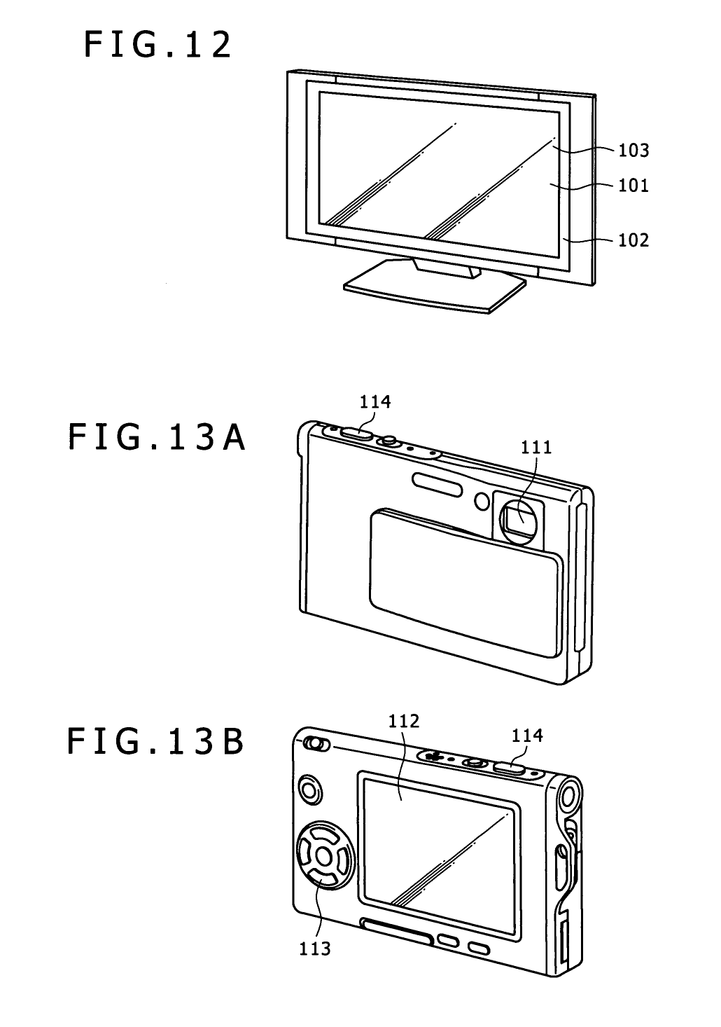

FIGS. 12 to 16G illustrate examples of an electronic apparatus in which a display according to an embodiment of the present invention as described above is used as a display unit. The displays according to embodiments of the invention are applicable to display units in electronic apparatuses in any field which display video signals inputted to the electronic apparatuses and, further, video signals produced in the electronic apparatuses. An example of electronic apparatuses according to an embodiment of the present invention is hereinafter described.

FIG. 12 is a perspective view of a television to which the present invention is applied. The television according to this application example includes an image-displaying screen unit 101 having a front panel 102, a filter glass 103 and the like, and is manufactured by using a display according to an embodiment of the invention as the image-displaying screen unit 102.

FIGS. 13A and 13B illustrate a digital camera to which the present invention is applied, wherein FIG. 13A is a perspective view from the front side, and FIG. 13B is a perspective view from the rear side. The digital camera according to this application example includes a flash light emitting unit 111, a display unit 112, a menu switch 113, a shutter button 114 and the like, and is manufactured by use of the display according to an embodiment of the invention as the display unit 112.

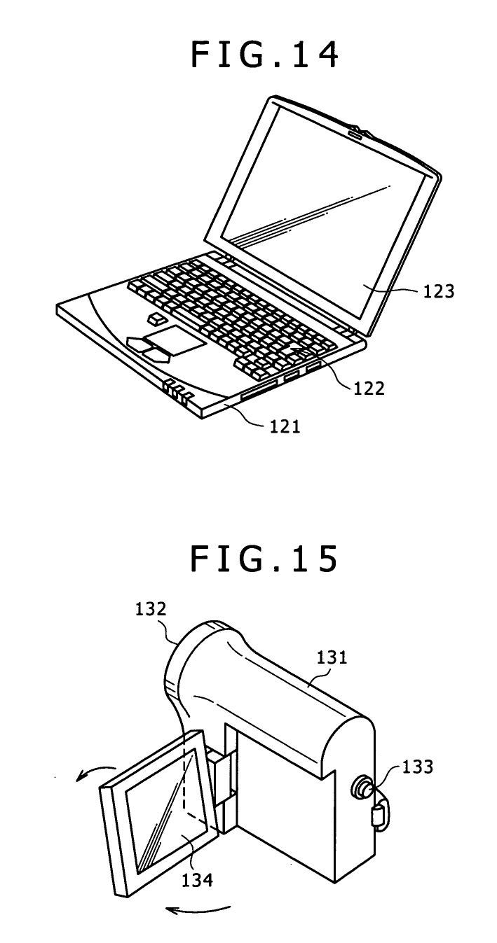

FIG. 14 is a perspective view of a notebook sized personal computer to which the present invention is applied. The notebook sized personal computer according to this application example includes a main body 121, a keyboard 122 operated to input characters and the like, a display unit 123 for displaying images, and the like, and the display according to an embodiment of the invention is used as the display unit 123.

FIG. 15 is a perspective view of a video camera to which the present invention is applied. The video camera according to this application example includes a main body unit 131, a lens 132 provided at a side surface facing forwards for shooting a subject, a start/stop switch 133 operated at the time of shooting, a display unit 134 and the like, and a display according to an embodiment of the invention is used as the display unit 134.

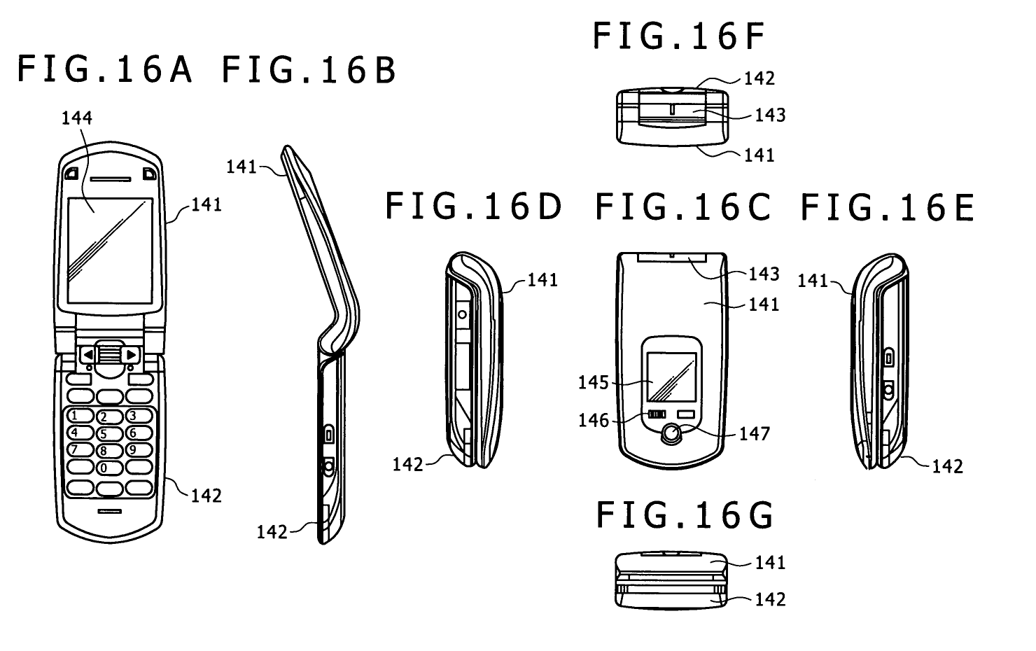

FIGS. 16A to 16G are perspective views of a portable terminal device, for example, a cellular phone, using a display according to an embodiment of the invention, wherein FIG. 16A is a front view of the device in an opened state, FIG. 16B is a side view of the device, FIG. 16C is a front view of the device in a closed state, FIG. 16D is a left side view of the device, FIG. 16E is a right side view of the device, FIG. 16F is a top view, and FIG. 16G is a bottom view. The cellular phone according to this application example includes an upper casing 141, a lower casing 142, a link section (here, a hinge section) 143, a display 144, a sub-display 145, a picture light 146, a camera 147 and the like, and is manufactured by using a display(s) according to an embodiment(s) of the invention as the display 144 and/or the sub-display 145.

Incidentally, in the seventh embodiment above, the configurations of electronic apparatuses including the display according to embodiments of the present invention is used have been described. However, the electronic apparatus pertaining to the invention is widely applicable to electronic apparatuses in which the thin film transistors according to the first embodiment or the second embodiment of the invention are provided. Specifically, for example, the electronic apparatus pertaining to the invention is applicable to semiconductor devices which are configured by use of thin film transistors and other elements, such as semiconductor devices for memory, e.g., DRAM, and driving circuits for light receiving elements, and so on, whereby similar effects to the above-mentioned can be obtained.

The present application contains subject matter related to that disclosed in Japanese Priority Patent Application JP 2009-122756 filed in the Japan Patent Office on May 21, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor comprising:
a semiconductor layer including an amorphous oxide, and a source electrode and a drain electrode which are provided in contact with the semiconductor layer,
wherein the source electrode and the drain electrode are formed by use of iridium or iridium oxide.

2. The thin film transistor according to claim 1,
wherein those portions of the source electrode and the drain electrode which are in contact with the semiconductor layer are formed by use of iridium or iridium oxide.

3. The thin film transistor according to claim 2,
wherein the semiconductor layer is covered with an insulating film which has an oxide material.

4. The thin film transistor according to claim 3,
wherein the insulating film having the oxide material is provided in contact with the semiconductor layer.

5. The thin film transistor according to claim 4,
wherein one of the insulating film is a gate insulating film.

6. The thin film transistor according to claim 1,
wherein the semiconductor layer is covered with an insulating film which has an oxide material.

7. The thin film transistor according to claim 6,
wherein the insulating film having the oxide material is provided in contact with the semiconductor layer.

8. The thin film transistor according to claim 6,
wherein one of the insulating film is a gate insulating film.

9. A display comprising:
a thin film transistor and a pixel electrode connected to the thin film transistor, the thin film transistor including a source electrode and a drain electrode which are provided in contact with a semiconductor layer having an amorphous oxide,
wherein the source electrode and the drain electrode are formed by use of iridium or iridium oxide.

10. An electronic apparatus comprising:
a thin film transistor including a source electrode and a drain electrode which are provided in contact with a semiconductor layer having an amorphous oxide,
wherein the source electrode and the drain electrode are formed by use of iridium or iridium oxide.
